(19) United States
(12) Patent Application Publication
(10) Pub. No.: US 2012/0119207 A1
(43) Pub. Date: May 17, 2012

(54) INTERCONNECTION STRUCTURE AND METHOD FOR MANUFACTURING THE SAME, AND DISPLAY DEVICE INCLUDING INTERCONNECTION STRUCTURE

(75) Inventors: Hiroshi Goto, Kobe-shi (JP); Takeaki Maeda, Hyogo (JP)

(73) Assignee: Kabushiki Kaisha Kobe Seiko Sho (Kobe Steel, Ltd.), Kobe-shi (JP)

(21) Appl. No.: 13/387,522

(22) PCT Filed: Jul. 27, 2010
(86) PCT No.: PCT/JP10/62648

§ 371 Date: Jan. 27, 2012

(30) Foreign Application Priority Data
Jul. 27, 2009 (JP) 2009-174416

(51) Int. Cl. H01L 29/24; H01L 21/20

(52) U.S. Cl. 257/43; 438/478; 257/E29.102; 257/E21.09

(57) ABSTRACT

Disclosed is an interconnection structure which, in a display device such as an organic EL display and a liquid crystal display, is capable of stably connecting a semiconductor layer directly to an Al-base film constituting, for example, a source electrode or a drain electrode; and which hardly causes galvanic corrosion between the semiconductor layer and the Al-base film in an electrolyte solution to be used in a wet process and is able to suppress stripping of the Al-base film. It is an interconnection structure including a semiconductor layer of a thin-film transistor and an Al alloy film connected directly to the semiconductor layer above a substrate in this order from the side of the substrate, wherein the semiconductor layer is composed of an oxide semiconductor, and the Al alloy film contains at least one of Ni and Co.

### TECHNICAL FIELD

The present invention relates to an interconnection structure including a semiconductor layer of a thin-film transistor and an Al alloy film connected directly to the semiconductor layer in this order from the side of a substrate, wherein the semiconductor layer is composed of an oxide semiconductor layer composed of an oxide semiconductor, and a method for manufacturing the same; and a display device including the interconnection structure. The interconnection structure of the invention is representatively used for, for example, flat panel displays such as a liquid crystal display (liquid crystal displace device) and an organic EL display. In the following, a liquid crystal display device will be representatively taken up and explained, but it should not be construed that the invention is limited thereto.

### BACKGROUND ART

In recent years, displays using an oxide semiconductor for a semiconductor layer (channel layer) of an organic EL displayer or a liquid crystal display have been developed. For example, in Patent Document 1, as a transparent semiconductor layer in a semiconductor device, one obtained by using any one of zinc oxide (ZnO), cadmium oxide (CdO), and a compound or mixture of zinc oxide (ZnO) to which a IIB element, a IIA element or a VIB element is added, and doping with a 3d transition metal element, a rare earth element or an impurity capable of making the resistance high without losing transparency of the transparent semiconductor, is used.

The oxide semiconductor has a high carrier mobility as compared with amorphous silicon which has hitherto been used as a material of the semiconductor layer. Furthermore, since the oxide semiconductor can be deposited by a sputtering method, it is able to contrive to make a substrate temperature low as compared with the case of the formation of a layer composed of the foregoing amorphous silicon. As a result, resin substrates with low heat resistance, and the like can be used, and therefore, it is possible to realize a flexible display.

As an example of using such an oxide semiconductor for a semiconductor device, for example, in Patent Document 1, one obtained by using any one of zinc oxide (ZnO), cadmium oxide (CdO), and a compound or mixture of zinc oxide (ZnO) to which a IIB element, a IIA element or a VIB element is added, and doping with a 3d transition metal element, a rare earth element or an impurity capable of making the resistance high without losing transparency of the transparent semiconductor, is used. Of the oxide semiconductors, oxides containing at least one or more elements selected from the group consisting of In, Ga, Zn, and Sn (e.g., IGOZO, ZTO, IZO, ITO, ZnO, AZTO, GZTO) have a very high carrier mobility, and therefore, they are preferably used.

### PRIOR ART DOCUMENT

### Patent Document

Patent Document 1: JP-A-2002-76356

### SUMMARY OF THE INVENTION

### Problems to be Solved by the Invention

For interconnection materials in TFT substrates, such as gate interconnections and source-drain interconnections, pure Al or an Al alloy such as Al—Nd (these will be hereinafter sometimes summarized and referred to as Al-base) is used for many purposes, for the reasons that the electrical resistance is small, and micromachining is easily performed, and the like.

But, for example, in the case of a laminated structure not only using an oxide semiconductor for a semiconductor layer of a bottom gate type TFT but using an Al-base film for a source electrode or a drain electrode, there is a problem that when the oxide semiconductor layer is connected directly to the Al-base film constituting a source electrode or a drain electrode, high-resistance aluminum oxide is formed at an interface between the oxide semiconductor layer and the Al-base film to increase the connection resistance (contact resistance, electrical contact resistance), whereby the display quality of a screen is lowered.

Also, as a method for forming the foregoing laminated structure, there may be considered adoption of a “lift-off method” in which after forming a desired pattern and a reverse pattern thereof with a lift-off resist on a substrate, an Al-base film is formed, and an unnecessary part is removed with an organic solvent or a stripping solution together with the lift-off resist, thereby obtaining the desired pattern. But, in this method, it is extremely difficult to form a large-area pattern uniformly and in a good yield while suppressing reattachment of Al-base metal pieces as lifted off. Then, as a method for forming the foregoing laminated structure, there may be considered application of photolithography and wet etching process. But, there is a problem that in patterning by photolithography, a possibility that a developing solution permeates between the Al-base film constituting a source electrode or a drain electrode and the oxide semiconductor layer, whereby the foregoing Al-base film is stripped by galvanic corrosion is high.

The invention has been made upon paying attention to such circumstances, and an object thereof is to provide an interconnection structure which, in a display device such as an organic EL display and a liquid crystal display, is capable of stably connecting an oxide semiconductor layer directly to an Al-base film constituting, for example, a source electrode or a drain electrode; and which hardly causes galvanic corrosion between the oxide semiconductor layer and the Al-base film in an electrolyte solution (for example, a developing solution) to be used in a wet process (for example, the foregoing photolithography) and is able to suppress stripping of the Al-base film, and a method for manufacturing the same, and the foregoing display device including the interconnection structure.

### Means for Solving the Problems

The invention encompasses the following embodiments.

(1) An interconnection structure comprising a semiconductor layer of a thin-film transistor and an Al alloy film connected directly to the semiconductor layer above a substrate in this order from the side of the substrate, wherein

the semiconductor layer is composed of an oxide semiconductor, and

the Al alloy film contains at least one of Ni and Co.

(2) The interconnection structure according to (1), wherein the Al alloy film is connected directly to a transparent conductive film constituting a pixel electrode.

(3) The interconnection structure according to (1) or (2), wherein the Al alloy film contains at least one of Ni and Co in an amount of from 0.1 to 2 atomic %.

(4) The interconnection structure according to any one of (1) to (3), wherein the Al alloy film further contains at least one of Cu and Ge.

(5) The interconnection structure according to (4), wherein the Al alloy film contains at least one of Cu and Ge in an amount of from 0.05 to 2 atomic %.

(6) The interconnection structure according to any one of (1) to (5), wherein the oxide semiconductor is composed of an oxide containing at least one element selected from the group consisting of In, Ga, Zn, Ti, and Sn.

(7) The interconnection structure according to any one of (1) to (6), wherein the Al alloy film further contains at least one kind selected from the group consisting of Nd, Y, Fe, Ti, V, Zr, Nb, Mo, Hf, Ta, Mg, Cr, Mn, Ru, Rh, Pd, Ir, Pt, La, Gd, Tb, Dy, Sr, Sm, Ge and Bi.

(8) The interconnection structure according to (7), wherein the Al alloy film contains at least one kind selected from the group consisting of Nd, La, and Gd.

(9) The interconnection structure according to any one of (1) to (8), wherein at least one of a source electrode of the thin-film transistor and a drain electrode of the thin-film transistor is composed of the Al alloy film.

(10) A display device including the interconnection structure according to any one of (1) to (9).

(11) A method for manufacturing the interconnection structure according to any one of (1) to (9), the method including a step of depositing the semiconductor layer and a step of depositing the Al alloy film, wherein

a part of at least one of Ni and Co is deposited and/or enriched at an interface of the semiconductor layer and the Al alloy film connected directly thereto by

setting a substrate temperature during the deposition of the Al alloy film to 200° C. or higher; and/or

performing a heat treatment at a temperature of 200° C. or higher after the deposition of the Al alloy film.

### Advantage of the Invention

According to the invention, an interconnection structure (for example, a TFT substrate) which, in a display device such as an organic EL display and a liquid crystal display, exhibits a high mobility and is able to connect an oxide semiconductor layer capable of achieving deposition at a lower temperature as compared with amorphous Si or poly-Si, directly to an Al-base film constituting, for example, a source electrode or a drain electrode, and which has high reliability because in a wet process in manufacturing steps of a display device, galvanic corrosion is hardly caused in the directly connected part as described above, and an display device including the same can be manufactured in a simple and easy process.

### BRIEF DESCRIPTION OF THE DRAWINGS

FIG. 1 is a schematic cross sectional explanatory view showing a configuration of an interconnection structure (TFT substrate) according to Embodiment 1 of the invention.

FIG. 2 is a schematic cross sectional explanatory view showing a configuration of an interconnection structure (TFT substrate) according to Embodiment 2 of the invention.

FIGS. 3(a) to 3(f) are each an explanatory view showing an example of manufacturing steps of the interconnection structure shown in FIG. 1 in order.

FIGS. 4(a) to 4(g) are each an explanatory view showing an example of manufacturing steps of the interconnection structure shown in FIG. 2 in order.

### EMBODIMENTS FOR CARRYING OUT THE INVENTION

In order to solve the foregoing problems, the present inventors made extensive and intensive investigations. As a result, it has been found that in an interconnection structure including a semiconductor layer of a thin-film transistor and an Al alloy film connected directly to the foregoing semiconductor layer in this order from the side of a substrate, wherein the foregoing semiconductor layer is composed of an oxide semiconductor, and the foregoing Al alloy film contains Ni and/or Co, it is possible to stably connect the semiconductor layer directly to the foregoing Al alloy film constituting, for example, a source electrode or a drain electrode; and that in an electrolyte solution to be used in a wet process, such as a developing solution, galvanic corrosion is hardly caused between the foregoing semiconductor layer and Al alloy film, and film stripping can be suppressed.

Preferred embodiments of an interconnection structure and a method for manufacturing the same according to the invention are hereunder described by reference to the drawings, but it should not be construed that the invention is limited thereto.

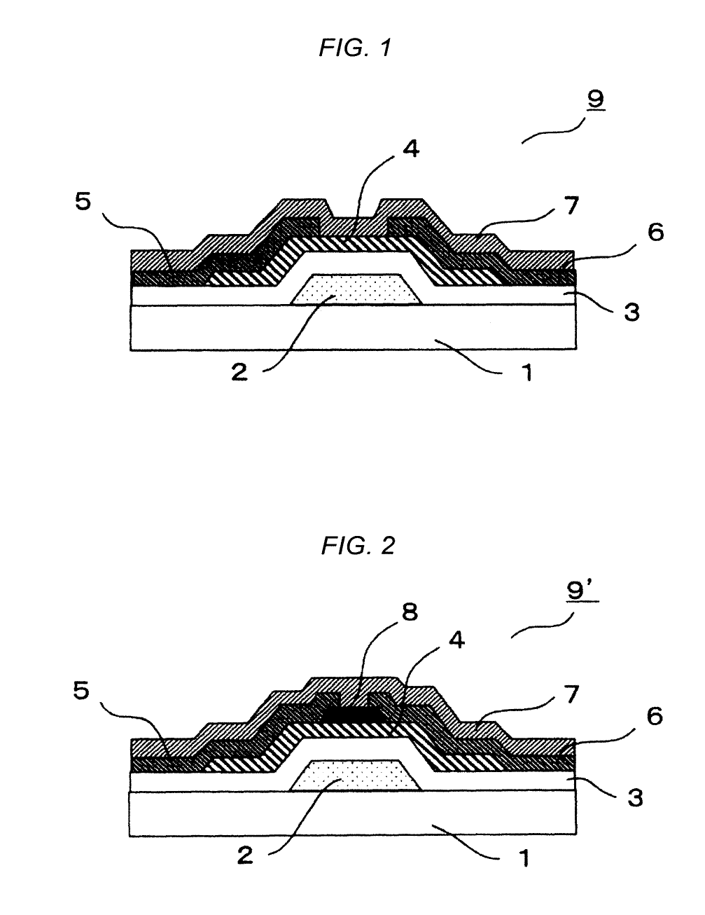

FIG. 1 is a schematic cross sectional explanatory view explaining a preferred embodiment (Embodiment 1) of an interconnection structure according to the invention. A TFT substrate 9 shown in FIG. 1 is of a bottom gate type and has a structure in which a gate electrode 2, a gate insulating film 3, a semiconductor layer 4, a source electrode 5/drain electrode 6, and a protective layer 7 are laminated successively from the side of a substrate 1.

Also, FIG. 2 is a schematic cross sectional explanatory view explaining another preferred embodiment (Embodiment 2) of an interconnection structure according to the invention. A TFT substrate 9′ shown in FIG. 2 is also of a bottom gate type and has a structure in which a gate electrode 2, a gate insulating film 3, a semiconductor layer 4, a channel protective layer 8, a source electrode 5/drain electrode 6, and a protective layer 7 are laminated successively from the side of a substrate 1.

The semiconductor layer 4 which is used in the invention is not particularly limited so far as it is an oxide semiconductor which is used in a liquid crystal display device or the like. For example, one composed of an oxide containing at least one element selected from the group consisting of In, Ga, Zn, Ti, and Sn is used. Specific examples of the foregoing oxide include transparent oxides such as In oxide, In—Sn oxide, In—Zn oxide, In—Sn—Zn oxide, In—Ga oxide, Zn—Sn oxide, Zn—Ga oxide, In—Ga—Zn oxide, Zn oxide and Ti oxide; and AZTO and GZTO which are obtained by doping Zn—Sn oxide with Al and Ga, respectively.

The foregoing Al alloy film (the source electrode 5 and/or drain electrode 6 in Embodiments 1 and 2), which is connected directly to the semiconductor layer, contains Ni and/or Co. In this way, by allowing the Al alloy film to contain Ni and/or Co, the electrical contact resistance between the Al alloy film constituting the source electrode 5 and/or drain electrode 6 and the semiconductor layer 4 can be reduced. Also, the foregoing galvanic corrosion can be suppressed, and film stripping can be suppressed.

In order to sufficiently exhibit such effects, a content of Ni and/or Co (when Ni or Co is contained alone, the content is an alone content, and in the case of containing the both, the content is a total content thereof) is preferably approximately 0.1 atomic % or more, more preferably 0.2 atomic % or more, and still more preferably 0.5 atomic % or more. On the other hand, when the content of the foregoing element or elements is too large, there is a concern that an electrical resistivity of the Al alloy film increases, and therefore, an upper limit thereof is preferably 2 atomic %, and more preferably 1 atomic %.

As the foregoing Al alloy film which is used in the invention, examples thereof include an Al alloy containing Ni and/or Co in the foregoing content, with the balance being Al and inevitable impurities.

In the foregoing Al alloy film, Cu and/or Ge can be further contained in an amount of from 0.05 to 2 atomic %. These elements are an element capable of contributing to a more reduction of the contact resistance, and they may be added alone or in combination. In order to sufficiently exhibit such effects, a content of the foregoing element(s) (when Cu or Ge is contained alone, the content is an alone content, and in the case of containing the both, the content is a total content thereof) is preferably approximately 0.05 atomic % or more, more preferably 0.1 atomic % or more, and still more preferably 0.2 atomic %. On the other hand, when the content of the foregoing element(s) is too large, there is a concern that an electrical resistivity of the Al alloy film increases, and therefore, an upper limit thereof is preferably 2 atomic %, and more preferably 1 atomic %.

In the foregoing Al alloy film, it is tolerable to add, as other alloy component, a heat resistance improving agent (at least one kind of Nd, Y, Fe, Ti, V, Zr, Nb, Mo, Hf, Ta, Mg, Cr, Mn, Ru, Rh, Pd, Ir, Pt, La, Gd, Tb, Dy, Sr, Sm, Ge, and Bi) in an amount of from 0.05 to 1 atomic % in total, preferably from 0.1 to 0.5 atomic % in total, and more preferably from 0.2 to 0.35 atomic % in total.

As the foregoing heat resistance improving element, at least one kind selected from the group consisting of Nd, La, and Gd is more preferable.

The content of the respective alloy elements in the foregoing Al alloy film can be determined by, for example, an ICP emission spectrometry (inductively coupled plasma emission spectrometry) method.

In the foregoing Embodiments 1 and 2, the Al alloy film of the invention is adopted for the source electrode and/or drain electrode, and a component composition of other interconnection part (for example, the gate electrode 2) is not particularly limited. However, the gate electrode, a scanning line (not shown), and a drain interconnection part (not shown) in a signal line may also be constituted of the foregoing Al alloy film. In that case, all of the Al alloy interconnections in the TFT substrate can be formed of the same component composition.

Also, the interconnection structure of the invention can be adopted for not only a bottom gate type TFT substrate as in the foregoing Embodiments 1 and 2 but a top gate type TFT substrate.

The substrate 1 is not particularly limited so far as it is one to be used for a liquid crystal display device or the like. Examples thereof include a transparent substrate represented by a glass substrate and the like. A material of the glass substrate is not particularly limited so far as it is one to be used for a display device, and examples thereof include alkali-free glass, glass having a high strain point, soda lime glass, and so on. Examples thereof also include substrates such as metal foils and the like; and heat-resistant resin substrates such as imide resins and the like.

As the gate insulating film 3, the protective layer 7, and the channel protective layer 8, examples thereof include one composed of a dielectric substance (for example, SiN, SiON, or SiO₂). SiO₂ or SiON is preferable. This is because the oxide semiconductor is deteriorated in excellent properties thereof under a reducing atmosphere, and therefore, the use of SiO₂ or SiON capable of undergoing deposition under an oxidizing atmosphere is recommended.

As a transparent conductive film (not shown in FIGS. 1 and 2) constituting a pixel electrode, examples thereof include an oxide conductive film which is usually used for a liquid crystal display device or the like. Typical examples thereof include amorphous ITO, poly-ITO, IZO, and ZnO.

Also, it is preferable that the transparent conductive film constituting a pixel electrode is connected directly to the foregoing Al alloy film.

In the invention, it is a preferred embodiment that at an interface between the oxide semiconductor layer 4 and the foregoing Al alloy film (for example, the source electrode 5 and/or drain electrode 6) connected directly thereto, a deposit containing Ni and/or Co is deposited; and/or an enriched layer containing Ni and/or Co is formed.

In view of the fact that such a deposit or enriched layer is formed partially or entirely as a region with low electrical resistance, it may be considered that the electrical contact resistance between the conductor layer 4 and the Al alloy film constituting the source electrode 5 and/or drain electrode 6 is greatly reduced.

The foregoing deposition and/or enrichment of Ni and/or Co can be realized by setting a substrate temperature during the deposition of the foregoing Al alloy film (hereinafter referred to as “deposition temperature”) to 200° C. or higher; and/or performing a heat treatment at a temperature of 200° C. or higher after the deposition of the foregoing Al alloy film.

Preferably, the deposition temperature of the foregoing Al alloy film is set to 200° C. or higher; and more preferably, not only the deposition temperature of the foregoing Al alloy film is set to 200° C. or higher, a heat temperature is performed at a temperature of 200° C. or higher but after the deposition of the foregoing Al alloy film.

In all of the cases, the temperature is preferably 250° C. or higher. Even when the foregoing substrate temperature or heating temperature is more increased, a reducing effect of the contact resistivity by deposition/enrichment of Ni and/or Co is saturated. From the viewpoint of a heat-resistant temperature of a base material or the like, it is preferable to set up the foregoing substrate temperature or heating temperature to 300° C. or lower. A heating time at 200° C. or higher is preferably 5 minutes or more and 60 minutes or less.

Heating (heat treatment) which is performed after deposition of the foregoing Al alloy film may be performed for the purpose of the foregoing deposition/enrichment, or a heat history after forming the foregoing Al alloy film (for example, a step of depositing a protective layer) may satisfy the foregoing temperature/time.

In manufacturing the interconnection structure of the invention, there are no particular limitations, except that not only the requirements of the invention are satisfied, but the deposition condition of the Al alloy film and/or the heat treatment/heat history condition of the Al alloy film is controlled to the above-recommended condition, and general steps of a display device may be adopted.

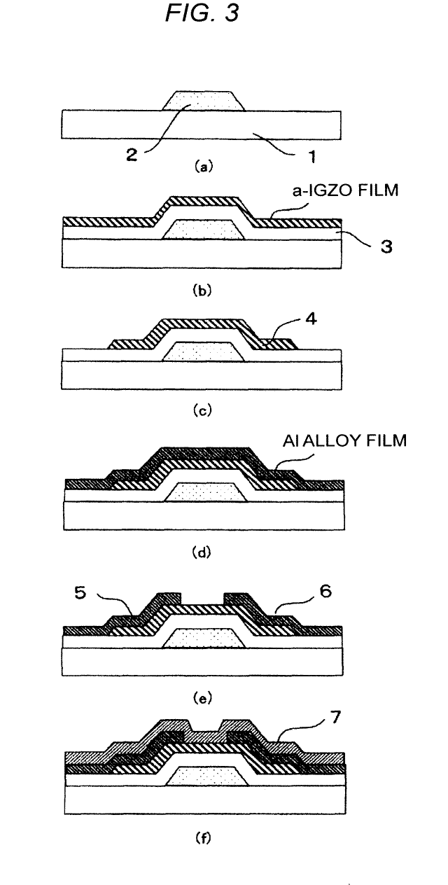

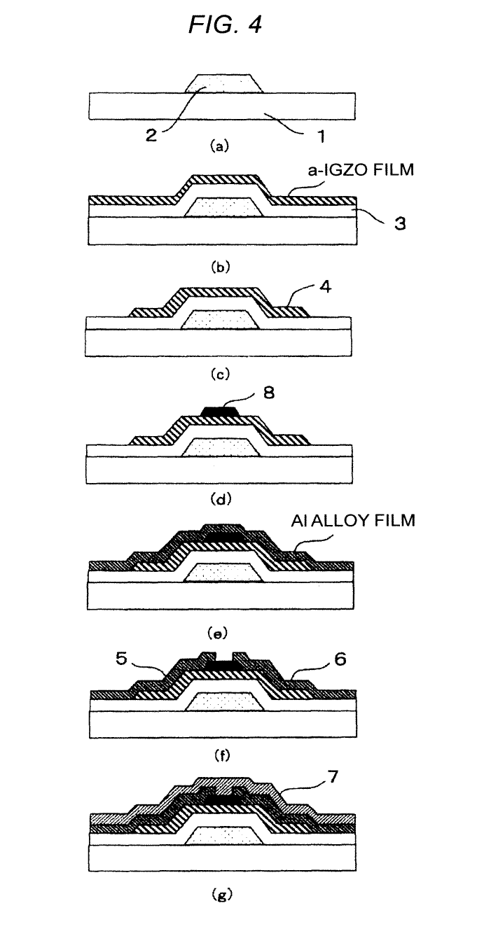

An example of the manufacturing method of the TFT substrate shown in the foregoing FIG. 1 is hereunder explained by reference to FIGS. 3(a) to 3(f). In FIGS. 3(a) to 3(f), reference symbols which are the same as those in the foregoing FIG. 1 are given. The following is explained as an example of the manufacturing method, but it should not be construed that the invention is limited thereto (the same is also applicable to FIG. 4).

First of all, an Al alloy film (for example, an Al-2 at % (atomic %)Ni-0.35 at % La alloy film) having a film thickness of about 200 nm is laminated on a glass substrate 1 by adopting a sputtering method. This Al alloy film is subjected to patterning to form a gate electrode 2 (see FIG. 3(a)). At that time, in FIG. 3(b) as described later, it is recommendable that the periphery of the Al alloy film constituting the gate electrode 2 is etched in a taper shape of from about 30° to 40° so as to improve coverage of a gate insulating film 3.

Subsequently, an SiN film as the gate insulating film 3 is deposited in a film thickness of about 300 nm by a CVD method. Furthermore, an oxide semiconductor layer composed of a-IGZO (film thickness: about 30 nm) as a semiconductor layer 4 is deposited by performing reactive sputtering using a target having a composition of, for example, In/Ga/Zn (atomic ratio: 1/1/1) in a mixed gas atmosphere of Ar and O₂ (oxygen content: 1 vol %) under a condition of a substrate temperature at room temperature (see FIG. 3(b)).

Subsequently, photolithography is performed, and the a-IGZO film is etched with oxalic acid, thereby forming a semiconductor layer (oxide semiconductor layer) 4 (see FIG. 3(c)).

Subsequently, an Ar plasma treatment is performed. According to this Ar plasma treatment, ohmic contact between the semiconductor layer 4 and an Al alloy film constituting a source electrode 5/drain electrode 6 as described later is obtained, whereby contact properties between the semiconductor layer 4 and the foregoing Al alloy film can be improved. In detail, it may be considered that by irradiating an Ar plasma in a contact interface part between the semiconductor layer 4 and the Al alloy film prior to the deposition of the foregoing Al alloy film, an oxygen deficiency is produced in a part exposed to the plasma, and conductivity is enhanced, whereby the contact properties with the foregoing Al alloy film can be improved.

After performing the foregoing Ar plasma treatment, an Al alloy film (for example, an Al-2 at % Ni-0.35 at % La alloy film) is formed in a film thickness of about 200 nm at a deposition temperature of 200° C. or higher by a sputtering method. Alternatively, after performing the foregoing Ar plasma treatment, the foregoing Al alloy film is formed in a film thickness of about 200 nm, for example, at a deposition temperature of 150° C. by a sputtering method, and thereafter, a heat treatment is performed, for example, at 250° C. for 30 minutes (see FIG. 3(d)).

The foregoing Al alloy film is subjected to photolithography and etching, thereby forming the source electrode 5 and the drain electrode 6 (see FIG. 3(e)).

Then, a protective layer 7 composed of SiO₂ is formed by a CVD method, whereby the TFT substrate 9 in FIG. 1 can be obtained (see FIG. 3(f)).

Next, an example of the manufacturing method of the TFT substrate shown in the foregoing FIG. 2 is hereunder explained by reference to FIGS. 4(a) to 4(g). In FIGS. 4(a) to 4(g), reference symbols which are the same as those in the foregoing FIG. 2 are given.

First of all, an Al alloy film (for example, an Al-2 at % Ni-0.35 at % La alloy film) having a film thickness of about 200 nm is laminated on a glass substrate 1 by adopting a sputtering method. This Al alloy film is subjected to patterning to form a gate electrode 2 (see FIG. 4(a)). At that time, in FIG. 4(b) as described later, it is recommendable that the periphery of the Al alloy film constituting the gate electrode 2 is etched in a taper shape of from about 30° to 40° so as to improve coverage of a gate insulating film 3.

Subsequently, an SiN film as the gate insulating film 3 is deposited in a film thickness of about 300 nm by a CVD method. Furthermore, an oxide semiconductor layer composed of a-IGZO (film thickness: about 30 nm) as a semiconductor layer 4 is deposited by performing reactive sputtering using a target having a composition of, for example, In/Ga/Zn (atomic ratio: 1/1/1) in a mixed gas atmosphere of Ar and O₂ (oxygen content: 1 vol %) under a condition of a substrate temperature at room temperature (see FIG. 4(b)).

Subsequently, photolithography is performed, and the a-IGZO film is etched with oxalic acid, thereby forming a semiconductor layer (oxide semiconductor layer) 4 (see FIG. 4(c)).

Subsequently, an SiO₂ film is formed in a film thickness of about 100 nm by a CVD method, followed by exposing from a rear surface of the glass substrate (surface on which the gate electrode and the like are not formed) while using the gate electrode as a mask, thereby performing photolithography; and a channel protective layer 8 is formed by dry etching (see FIG. 4(d)).

Similar to the case of the foregoing Embodiment 1, after performing the foregoing Ar plasma treatment, an Al alloy film (for example, an Al-2 at % Ni-0.35 at % La alloy film) is formed in a film thickness of about 200 nm at a deposition temperature of 200° C. or higher by a sputtering method. Alternatively, similar to the case of the foregoing Embodiment 1, after performing the foregoing Ar plasma treatment, the foregoing Al alloy film is formed in a film thickness of about 200 nm, for example, at a deposition temperature of 150° C. by a sputtering method, and thereafter, a heat treatment is performed, for example, at 250° C. for 30 minutes (see FIG. 4(e)).

The foregoing Al alloy film is subjected to photolithography and etching, thereby forming the source electrode 5 and the drain electrode 6 (see FIG. 4(f)).

Then, a protective layer 7 composed of SiO₂ is formed by a CVD method, whereby the TFT substrate 9′ in FIG. 2 can be obtained (see FIG. 4(g)).

A display device can be accomplished by using the thus obtained TFT substrate by, for example, a generally adopted method.

### EXAMPLES

The invention is more specifically described below with reference to Examples, but it should not be construed that the invention is limited to the following Examples. The invention can also be practiced by applying modifications within a range adaptable to the purports described above and described below, and all of them are included in the technical scope of the invention.

(1) Kind of Metal Film and Contact Resistance

Contact resistance between a pure Al film or Al-2at % Ni-0.35 at % La alloy film and an oxide semiconductor layer was examined using a TLM device as formed in the following way and a TLM method.

In detail, first of all, an oxide semiconductor layer (film thickness: 30 nm) composed of a-IGZO was deposited on a surface of a glass substrate (Eagle 2000, manufactured by Corning Incorporated) by performing sputtering using a target having a composition of In/Ga/Zn (atomic ratio: 1/1/1) in a mixed gas atmosphere of Ar and O₂ (oxygen content: 1 vol %) under a condition of a substrate temperature at room temperature.

Subsequently, SiO₂ was deposited in a thickness of 200 nm by a CVD method; a contact part with a source electrode/drain electrode was subjected to patterning by photolithography; and contact hole etching was performed with an Ar/CHF₃ plasma by an RIE etching apparatus.

Subsequently, ashing was performed to remove a reaction layer of the resist surface, and thereafter, the resist was continuously completely stripped with a stripping solution (TOK106, manufactured by Tokyo Ohka Kogyo Co., Ltd.).

A pure Al film or an Al-2 at % Ni-0.35 at % La alloy film was formed as a source electrode/drain electrode in a film thickness of 200 nm thereon. In all of these cases, as for a deposition condition, argon was used as an atmospheric gas, a pressure was set to 2 mTorr, and a substrate temperature was set to room temperature or 200° C. Also, after the deposition, a part of the samples was subjected to a heat treatment at 250° C. for 30 minutes.

Subsequently, a pattern of the TLM device was formed by photolithography; the foregoing pure Al film or Al-2 at % Ni-0.35 at % La alloy film was etched while using the resist as a mask; and the resist was stripped. TLM devices composed of plural electrodes and having various distances between adjoining electrodes were obtained. The foregoing pattern of the TLM device was a pattern having a gap of 10 μm, 20 μm, 30 μm, 40 μm, and 50 μm, respectively in pitch and having a width of 150 μm and a length of 300 μm.

Using the thus obtained TLM devices, current-voltage properties between the plural electrodes were measured, thereby determining a resistance value between the respective electrodes. A contact resistivity was determined from a relation of the resistance value between the thus obtained respective electrode with the distance between the electrodes (TLM method).

In the foregoing measurement, three TLM devices were formed for each metal film and measured with respect to the foregoing contact resistivity, and an average value was determined. The results are shown in Table 1.

TABLE 1

| | | Substrate | | | | | |
|---|---|---|---|---|---|---|---|
| | Composition of | temperature during | Heat treatment | Contact resistance (Ω · cm²) | | | |
| No. | film * | deposition (° C.) | after deposition | TLM device 1 | TLM device 2 | TLM device 3 | Average value |
| 1 | Pure Al | Room temperature | No | 2.7 × 10⁻⁵ | 3.0 × 10⁻⁵ | 2.0 × 10⁻⁵ | 2.6 × 10⁻⁵ |
| 2 | | Room temperature | 250° C. × 30 min | 9.9 × 10⁻¹ | 1.5 × 10⁰ | 1.4 × 10⁻² | 8.3 × 10⁻¹ |
| 3 | Al—2Ni—0.35La | Room temperature | No | 3.6 × 10⁻⁵ | 6.2 × 10⁻⁵ | 1.0 × 10⁻⁵ | 3.6 × 10⁻⁵ |
| 4 | | Room temperature | 250° C. × 30 min | 9.0 × 10⁻² | 2.3 × 10⁻¹ | 9.0 × 10⁻³ | 1.1 × 10⁻¹ |
| 5 | Pure Al | 200° C. | No | 1.7 × 10⁻⁵ | 1.9 × 10⁻⁵ | 3.1 × 10⁻⁵ | 2.2 × 10⁻⁵ |
| 6 | | 200° C. | 250° C. × 30 min | 1.9 × 10⁰ | 6.6 × 10⁻¹ | 8.0 × 10⁻¹ | 1.1 × 10⁰ |
| 7 | Al—2Ni—0.35La | 200° C. | No | 1.1 × 10⁻⁵ | 2.3 × 10⁻⁵ | 2.6 × 10⁻⁵ | 2.0 × 10⁻⁵ |
| 8 | | 200° C. | 250° C. × 30 min | 1.5 × 10⁻⁵ | 3.0 × 10⁻⁵ | 3.3 × 10⁻⁵ | 2.6 × 10⁻⁵ |

* The numerical value is a proportion (atomic %) occupying in the Al alloy film.

From Table 1, the following consideration can be made. That is, in the case of the pure Al film, it is shown that by applying the heat treatment after the deposition (Nos. 2 and 6 in Table 1), the contact resistivity is greatly increased, thereby exhibiting a high resistivity, as compared with the case of applying no heat treatment (Nos. 1 and 5 in Table 1).

On the other hand, in the case of the Al-2 at % Ni-0.35 at % La alloy film, it is shown that in the case of performing deposition at a substrate temperature of 200° C. and applying the heat treatment (No. 8 in Table 1), not only the contact resistivity is sufficiently small as 2.6×10⁻⁵Ω·cm² in average, but the scattering is suppressed.

(2) Next, in order to examine the relations of the kind of an Al alloy film and a heat treatment condition with galvanic corrosion resistance and contact resistance, the following test was performed.

(2-1) Stripping Test (Evaluation of Galvanic Corrosion Resistance):

Evaluation of the galvanic corrosion resistance was performed in the following way. That is, a pure Al film or each of various Al alloy films shown in Table 1 (in all of the films, the film thickness was 200 nm) was formed on an oxide semiconductor (a-IGZO) layer as deposited in the same manner as that in the foregoing (1), except that the substrate temperature during the deposition and the heat treatment temperature after the deposition were changed as shown in Table 2. Thereafter, a resist was coated, exposed with ultraviolet rays, followed by developing with a developing solution containing 2.38% of TMAH; thereafter, the resist was removed with acetone; and the presence or absence of stripping of a pattern part of 100 μm square distributed on the entire surface of the substrate was observed by means of optical microscopic observation.

In detail, the image was cut into meshes of 5 μm square by means of image processing of the microscopic photograph. A part in which even a part of the meshes was stripped was counted as “stripped”, and a proportion of a number of meshes in the stripped part to a number of the whole of meshes was digitized as “stripping rate”.

Then, the foregoing stripping rate was determined in the following manner, thereby evaluating the galvanic corrosion resistance. The results are shown in Table 2.

A: The stripping rate is 0%.

B: The stripping rate is more than 0% and 20% or less.

C: The stripping rate is more than 20%.

(2-2) Measurement of Contact Resistivity

TLM devices were formed in the same manner as that in the foregoing (1), followed by measuring with respect to the contact resistivity by the TLM method. The foregoing contact resistivity was determined on the basis of the following evaluation criteria, thereby evaluating the contact resistance between the oxide semiconductor layer and the Al alloy film. As the oxide semiconductor layer, in addition to IGZO (In/Ga/Zn (atomic ratio)=1/1/1) as used in the foregoing (1), IGZO (In/Ga/Zn (atomic ratio)=2/2/1) and ZTO (Zn/Sn (atomic ratio)=2/1) were used and measured with respect to the contact resistance.

As for a deposition condition of IGZO (2/2/1) and ZTO (2/1), an Ar gas was used as an atmospheric gas; a pressure was set to 5 mTorr; a substrate temperature was set to 25° C. (room temperature); and a film thickness was set to 100 nm.

The results are shown in Table 3.

(Evaluation criteria of contact resistivity)

A: The contact resistivity is less than 1×10⁻² Ω·cm².

B: The contact resistivity is 1×10⁻² Ω·cm² or more and 1×10⁰ Ω·cm² or less.

C: The contact resistivity is more than 1×10⁰ Ω·cm².

TABLE 2

| | | | Heat treatment | Galvanic |
|---|---|---|---|---|
| | | Substrate temperature | temperature after | corrosion |
| No. | Composition of film | during deposition (° C.) | deposition (° C.) | resistance |
| 1 | Pure Al | Room temperature | — | C |
| 2 | | Room temperature | 200 | C |
| 3 | | Room temperature | 250 | C |
| 4 | | 200 | — | C |
| 5 | | 200 | 200 | C |
| 6 | | 200 | 250 | C |
| 7 | Al—0.2Ni—0.35La | Room temperature | — | B |
| 8 | | Room temperature | 200 | A |
| 9 | | 200 | — | A |
| 10 | | 200 | 200 | A |
| 11 | | 200 | 250 | A |
| 12 | Al—1Ni—0.5Cu—0.3La | Room temperature | — | B |
| 13 | | Room temperature | 200 | A |
| 14 | | 200 | — | A |
| 15 | | 200 | 200 | A |
| 16 | Al—2Ni—0.35La | Room temperature | — | B |
| 17 | | Room temperature | 150 | B |
| 18 | | Room temperature | 200 | A |
| 19 | | Room temperature | 250 | A |
| 20 | | 100 | — | B |
| 21 | | 100 | 200 | A |
| 22 | | 150 | — | A |
| 23 | | 150 | 200 | A |
| 24 | | 200 | — | A |
| 25 | | 200 | 150 | A |
| 26 | | 200 | 200 | A |
| 27 | | 200 | 250 | A |
| 28 | Al—0.2Co—0.5Ge—0.2La | Room temperature | — | B |
| 29 | | Room temperature | 200 | A |
| 30 | | 200 | — | A |
| 31 | | 200 | 200 | A |
| 32 | | 200 | 250 | A |
| 33 | Al—1Co—0.35La | Room temperature | — | B |
| 34 | | Room temperature | 200 | A |
| 35 | | 200 | — | A |
| 36 | | 200 | 200 | A |
| 37 | Al—0.1Ni—0.5Ge—0.27Nd | Room temperature | — | B |
| 38 | | Room temperature | 200 | A |
| 39 | | 200 | — | A |
| 40 | | 200 | 200 | A |
| 41 | | 200 | 250 | A |

*: The numerical value is a proportion (atomic %) occupying in the Al alloy film.

TABLE 3

| | Contact resistance with | Contact resistance with | Contact resistance |
|---|---|---|---|
| No. | IZGO (1/1/1) | IZGO (2/2/1) | with ZTO |
| 1 | A | A | A |
| 2 | B | B | B |
| 3 | C | C | C |
| 4 | A | A | A |
| 5 | C | C | C |
| 6 | C | C | C |
| 7 | A | A | A |
| 8 | B | B | B |
| 9 | A | A | A |
| 10 | A | A | A |
| 11 | A | A | A |
| 12 | A | A | A |
| 13 | B | B | B |
| 14 | A | A | A |
| 15 | A | A | A |
| 16 | A | A | A |
| 17 | B | B | B |
| 18 | B | B | B |
| 19 | B | B | B |
| 20 | A | A | A |
| 21 | B | B | B |
| 22 | A | A | A |
| 23 | B | B | B |
| 24 | A | A | A |
| 25 | A | A | A |
| 26 | A | A | A |
| 27 | A | A | A |
| 28 | A | A | A |
| 29 | B | B | B |
| 30 | A | A | A |
| 31 | A | A | A |
| 32 | A | A | A |
| 33 | A | A | A |
| 34 | B | B | B |
| 35 | A | A | A |
| 36 | A | A | A |
| 37 | A | A | A |
| 38 | B | B | B |
| 39 | A | A | A |
| 40 | A | A | A |
| 41 | A | A | A |

From Tables 2 and 3, the following consideration can be made. That is, in order to suppress stripping of the Al alloy film in the step of photolithography and also realize low contact resistance, it is shown that it is preferred that not only an Al alloy film containing Ni and/or Co is formed, but the substrate temperature during depositing this Al alloy film is set to 200° C. or higher. In the case where the deposition temperature is lower than 200° C., there was found tendency that when the heat treatment at a temperature of 200° C. or higher was applied after the deposition, the contact resistivity became slightly high. On the other hand, as described above, when the deposition was performed at a substrate temperature of 200° C. or higher, even in the case of applying the heat treatment at a temperature of 200° C. or higher after the deposition, low contact resistance was exhibited.

In particular, the following consideration on the Al-2 at % Ni-0.35 at % La alloy films (Nos. 16 to 27 in Table 2) is as follows. That is, in the case where the deposition temperature was lower than 200° C., when no heat treatment was applied thereafter (Nos. 16, 20 and 22), or the heat treatment temperature was lower than 200° C. ( 17), there was found tendency that the galvanic corrosion resistance was slightly inferior.

Also, in the case where the deposition temperature was lower than 200° C., and the heat treatment was applied (Nos. 17 to 19, 21 and 23), there was found tendency that the contact resistivity became slightly high as 1×10⁻² Q·cm² or more.

On the other hand, in the case where the substrate temperature during the deposition was 200° C. or higher, and no heat treatment was applied thereafter (No. 24), stripping was not caused in the photolithography. Also, the contact resistance showed a low value as 6×10⁻⁵ Ω·cm².

Also, even in the case where the substrate temperature during the deposition was 200° C. or higher, and the heat treatment was applied thereafter, it is shown that low contact resistance can be realized (Nos. 25 to 27). In particular, by setting the substrate temperature during the deposition to 200° C. or higher and applying the heat treatment at a temperature of 200° C. or higher (Nos. 26 and 27), the contact resistivity was sufficiently reduced to 2×10⁻⁵ Ω·cm². In this way, by performing deposition at a substrate temperature of 200° C. or higher, not only stripping in the photolithography can be prevented, but low contact resistance can be realized. Also, in order to achieve a lower contact resistivity, it is shown that it is preferred that after the deposition at a substrate temperature of 200° C. or higher, the heat treatment is further applied at a temperature of 200° C. or higher.

According to the foregoing lift-off method, even when no heat treatment was applied, the contact resistance between the pure Al film and the a-IGZO layer became low as 3×10⁻⁵ Ω·cm². However, when the photolithography was performed, there may be the case where stripping was caused. When the heat treatment was further applied at a temperature of 250° C. or higher, not only stripping was caused, but the contact resistivity became high as 1×10⁰ Ω·cm² or more.

Also, the following consideration on the Al-0.1 at % Ni-0.5 at % Ge-0.27 at % Nd alloy films (Nos. 37 to 41 in Table 2) is as follows. That is, in the case where the deposition temperature was lower than 200° C., when no heat treatment was applied thereafter (No. 37), there was found tendency that the galvanic corrosion resistance was slightly inferior.

Also, in the case where the deposition temperature was lower than 200° C., and the heat treatment was applied (No. 38), there was found tendency that the contact resistivity became slightly high.

On the other hand, in the case where the substrate temperature during the deposition was 200° C. or higher, and no heat treatment was applied thereafter (No. 39), stripping was not caused in the photolithography. Also, the contact resistance showed a low value.

Also, even in the case where the substrate temperature during the deposition was 200° C. or higher, and the heat treatment was further applied thereafter, it is shown that low contact resistance can be realized (Nos. 40 and 41). In particular, by setting the substrate temperature during the deposition to 200° C. or higher and applying the heat treatment at a temperature of 200° C. or higher, the contact resistivity exhibited a sufficiently low value. In this way, by performing deposition at a substrate temperature of 200° C. or higher, not only stripping in the photolithography can be prevented, but low contact resistance can be realized. Also, in order to achieve a lower contact resistivity, it is shown that it is preferred that after the deposition at a substrate temperature of 200° C. or higher, the heat treatment is further applied at a temperature of 200° C. or higher.

While the invention has been described in detail and with reference to specific embodiments thereof, it will be apparent to one skilled in the art that various changes and modifications can be made therein without departing from the spirit and scope thereof.

This application is based on Japanese Patent Application 2009-174416 filed on Jul. 27, 2009, and the entire subject matter of which is incorporated herein by reference.

### INDUSTRIAL APPLICABILITY

According to the invention, an interconnection structure (for example, a TFT substrate) which, in a display device such as an organic EL display and a liquid crystal display, exhibits a high mobility and is able to connect an oxide semiconductor layer capable of achieving deposition at a lower temperature as compared with amorphous Si or poly-Si, directly to an Al-base film constituting, for example, a source electrode or a drain electrode, and which has high reliability because in a wet process in manufacturing steps of a display device, galvanic corrosion is hardly caused in the directly connected part as described above, and an display device including the same can be manufactured in a simple and easy process.

### EXPLANATIONS OF REFERENCE SIGNS

1: Substrate
2: Gate electrode
3: Gate insulating film
4: Semiconductor layer
5: Source electrode
6: Drain electrode
7: Protective layer
8: Channel protective layer
9, 9′: TFT substrate

1. An interconnection structure including a semiconductor layer of a thin-film transistor and an Al alloy film connected directly to the semiconductor layer above a substrate in this order from the side of the substrate, wherein
the semiconductor layer is composed of an oxide semiconductor, and
the Al alloy film contains at least one of Ni and Co.

2. The interconnection structure according to claim 1, wherein the Al alloy film is connected directly to a transparent conductive film constituting a pixel electrode.

3. The interconnection structure according to claim 1, wherein the Al alloy film contains at least one of Ni and Co in an amount of from 0.1 to 2 atomic %.

4. The interconnection structure according to claim 1, wherein the Al alloy film further contains at least one of Cu and Ge.

5. The interconnection structure according to claim 4, wherein the Al alloy film contains at least one of Cu and Ge in an amount of from 0.05 to 2 atomic %.

6. The interconnection structure according to claim 1, wherein the oxide semiconductor is composed of an oxide containing at least one element selected from the group consisting of In, Ga, Zn, Ti, and Sn.

7. The interconnection structure according to claim 1, wherein the Al alloy film further contains at least one kind selected from the group consisting of Nd, Y, Fe, Ti, V, Zr, Nb, Mo, Hf, Ta, Mg, Cr, Mn, Ru, Rh, Pd, Ir, Pt, La, Gd, Tb, Dy, Sr, Sm, Ge and Bi.

8. The interconnection structure according to claim 7, wherein the Al alloy film contains at least one kind selected from the group consisting of Nd, La, and Gd.

9. The interconnection structure according to claim 1, wherein at least one of a source electrode of the thin-film transistor and a drain electrode of the thin-film transistor is composed of the Al alloy film.

10. A display device including the interconnection structure according to claim 1.

11. A method for manufacturing the interconnection structure according to claim 1, the method including a step of depositing the semiconductor layer and a step of depositing the Al alloy film, wherein
a part of at least one of Ni and Co is deposited and/or enriched at an interface of the semiconductor layer and the Al alloy film connected directly thereto by
setting a substrate temperature during the deposition of the Al alloy film to 200° C. or higher; and/or
performing a heat treatment at a temperature of 200° C. or higher after the deposition of the Al alloy film.
